(19) United States
(12) Patent Application Publication
(10) Pub. No.: US 2010/0165764 A1
(43) Pub. Date: Jul. 1, 2010

(54) MEMORY DEVICE WITH REDUCED CURRENT LEAKAGE

(75) Inventors: Luca PETRALIA, Adrano (CT) (IT); Danilo LAMEDICA, Vittoria (RG) (IT); Carmela CALAFATO, Pedara (CT) (IT); Salvatore CAPICI, Tremestieri Etneo (CT) (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 12/346,299

(22) Filed: Dec. 30, 2008

(51) Int. Cl. G11C 29/00; G11C 8/08; G11C 8/00

(52) U.S. Cl. 365/200; 365/230.06; 365/230.03

(57) ABSTRACT

The memory device (for example, a DRAM) includes a matrix of memory cells arranged in a plurality of rows and columns (for example, organized in pairs), which include redundancy rows and columns for replacing defective rows and columns. Each one of a plurality of bit lines is connected to the cells of a corresponding column, and each one of a plurality of word lines is connected to the cells of a corresponding row. A bit line driver is used for biasing the bit lines and a word line driver is used for biasing the word lines. Each one of a plurality of selectors is arranged along a potential conduction path between the bit line driver and the word line driver through a set of corresponding word lines and bit lines. A selection driver is used for setting each selector to a first resistance (for example, closed) if the corresponding rows and columns are non-defective or to a second resistance higher than the first resistance (for example, open) if at least one of the corresponding rows and columns is defective.

### FIELD OF THE INVENTION

Embodiments of the present invention relate to the field of microelectronics, and more specifically, to memory devices,

### BACKGROUND OF THE INVENTION

Memory devices are commonly used to store data in a number of applications. Particularly, non-volatile memory devices maintain the stored data even without power supply (so that they typically implement a mass storage). Conversely, volatile memory devices require the power supply to maintain the stored data; however, the volatile memories exhibit a very low access time, which make them well suited to use as Random Access Memories (RAMs). The RAMs may be classified into two main categories. When the stored data does not undergo any degradation (as far as the power supply is on), the RAMs are called static (or SRAMs); the SRAMs are faster and with lower power consumption (so that they are commonly used as cache memories). Conversely, when the stored data is to be periodically refreshed, the RAMs are called dynamic (or DRAMs); the DRAMs are cheaper and provide higher density (so that they are commonly used as working memories).

A generic memory device (for example, of the DRAM type) includes a matrix of memory cells arranged in rows and columns, with the memory cells of each row that are connected to a corresponding word line and the memory cells of each column that are connected to a corresponding bit line. Particularly, in a DRAM, the columns of memory cells are organized in pairs (with the memory cells of each pair of columns that are staggered to each other). Generally, the memory device also includes a number of redundancy rows and columns of memory cells, which are used to replace defective rows and columns, respectively (for example, when they are short-circuited). In this way, it is possible to avoid discarding the memory device even if it includes some defective rows and/or columns (until they do not exceed the available redundancy rows and columns that may be used in substitution of them).

However, the defective rows and columns establish conduction paths that generate a corresponding leakage current. Particularly, in the case of the DRAM, the leakage current flows between a voltage regulator (which is used to pre-charge and equalize any pairs of bit lines) and a charge pump (which is used to bias any word lines). This leakage current causes a significant power loss; the problem is particularly acute in the above-mentioned specific situation, wherein a far higher current is absorbed by the charge pump from the power supply of the memory device (i.e., the leakage current multiplied by a multiplication factor and divided by a yield of the charge pump).

An approach known in the art for coping with this problem includes adding a resistor along each conduction path of the leakage current. For example, for each pair of bit lines the resistor may be implemented with a pass transistor, which is arranged between the voltage regulator and a corresponding equalization block. All the pass-transistors are controlled by a common signal (for example, equal to a power supply voltage of the memory device), so as to bias them in a resistive condition. In this way, a resistance of the whole conduction path is increased by a suitable amount, thereby reducing the leakage current accordingly.

However, this approach involves a corresponding increase of a constant time of an RC circuit that is seen by the voltage regulator, and then of the time required to pre-charge the bit lines. Therefore, the resistance of the pass-transistor has to be maintained relatively low, so as to ensure that the bit lines correctly reach the desired voltage during the short time that is typically available for their pre-charging and equalization. In this case, the reduction of the leakage current so obtained may be not enough to reduce the power loss of the memory device significantly. Vice-versa, if the resistance of the pass-transistor is set to a relatively high value (so as to reduce the leakage current and then the power loss accordingly), it is necessary to increase the time required for pre-charging and equalizing the bit lines to the desired value, with a corresponding reduction of a working frequency of the memory device.

### SUMMARY OF THE INVENTION

Generally, the embodiments of the present invention are based on the objective of controlling the conduction paths of the leakage current individually.

Particularly, different aspects of the approach according to embodiments of the invention are set out in the independent claims. Further advantageous features of the approach are set out in the dependent claims.

More specifically, an aspect of the approach according to an embodiment of the invention proposes a memory device (for example, a DRAM). The memory device includes a matrix of memory cells arranged in a plurality of rows and columns (for example, organized in pairs), which include redundancy rows and columns for replacing defecting rows and columns (for example, when they are short-circuited). Each one of a plurality of bit lines is connected to the cells of a corresponding column, and each one of a plurality of word lines is connected to the cells of a corresponding row. A bit line driver is used for biasing the bit lines (for example, including an equalization block for pre-charging and equalizing each pair of bit lines to an equalization voltage provided by a voltage regulator). A word line driver is instead used for biasing the word lines (for example, to a biasing voltage provided by a charge pump). Each one of a plurality of selectors is arranged along a possible conduction path between the bit line driver and the word line driver through a set of corresponding word lines and bit lines (for example, between the voltage regulator and the equalization block of a corresponding pair of bit lines). A driver is used for setting each selector to a first resistance (for example, closed) if the corresponding rows and columns are non-defective or to a second resistance higher than the first resistance (for example, open) if at least one of the corresponding rows and columns is defective.

Another aspect of the approach according to an embodiment of the invention provides a system including one or more of such memory devices.

A further aspect of the approach according to an embodiment of the invention provides a corresponding method of operating such a memory device.

### BRIEF DESCRIPTION OF THE DRAWINGS

The approach according to one ore more embodiments of the invention, as well as further features and the advantages thereof, will be best understood with reference to the following detailed description, given purely by way of a nonrestrictive indication, to be read in conjunction with the accompanying drawings, in which:

FIG. 1 is a block diagram representation of a memory device in which the approach according to an embodiment of the invention is applicable;

FIG. 2 is schematic functional diagram of the memory device of FIG. 1;

FIG. 3 is a simplified circuit schematic diagram of a portion of the memory device of FIG. 1;

FIG. 4 is a simplified circuit schematic diagram of an exemplary implementation of the approach according to an embodiment of the present invention; and

FIG. 5 is a simplified circuit schematic diagram of an exemplary implementation of the approach according to another embodiment of the invention.

### DETAILED DESCRIPTION OF THE PREFERRED EMBODIMENTS

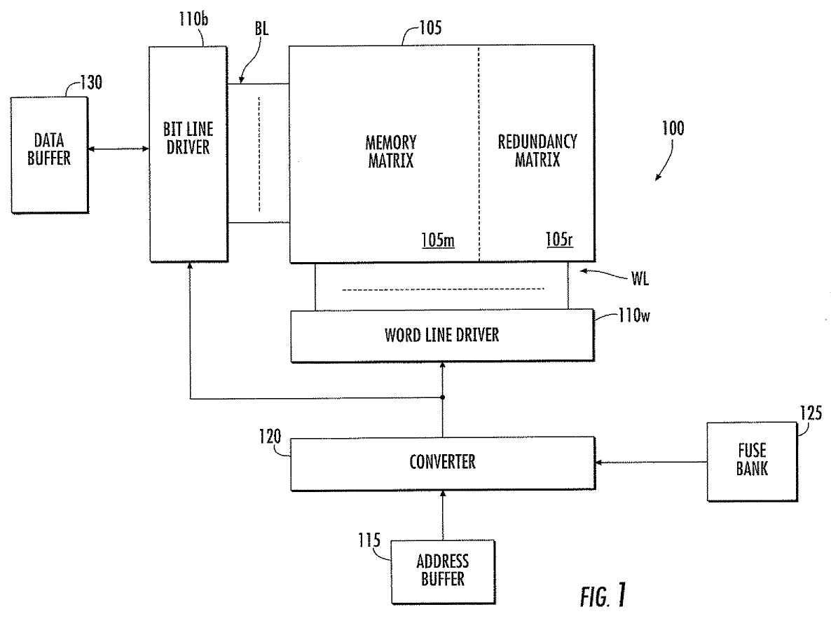

With reference in particular to FIG. 1, there is illustrated a conceptual block diagram representation of a memory device 100 in which the approach according to an embodiment of the invention is applicable. Particularly, the memory device 100 includes a volatile memory of the DRAM type. The memory device 100 is integrated in a chip of semiconductor material, and includes a matrix 105 of memory cells, each one for storing a bit (logic value 0 or 1); the matrix 105 is formed by one or more sectors of memory cells, which are arranged in rows and columns (for example, of the order of some thousands). The matrix 105 is logically partitioned into a portion 105m of functional memory cells and a portion 105r of redundancy (or spare) memory cells. The memory matrix 105m includes rows and columns of memory cells providing the required storage capacity of the memory device 100.

The redundancy matrix 105r instead includes a number of redundancy rows and columns of memory cells (for example, some hundreds) for replacing defective rows and columns, respectively, of the memory matrix 105m (such as when they are short-circuited). Typically, the redundancy rows and columns are arranged among the other rows and columns (for example, with a redundancy row and a redundancy column close to a corresponding set of rows and a corresponding set of columns that may be replaced by them).

The memory cells of each row (either in the memory matrix 105m or in the redundancy matrix 105r) are connected to a corresponding word line WL. The word lines WL are then connected to a word line driver 110w. Likewise, the memory cells of each column (either in the memory matrix 105m or in the redundancy matrix 105r) are connected to a corresponding bit line BL, and the bit lines BL are then connected to a bit line driver 110b.

The memory device 100 simultaneously reads and writes data at the level of words (for example, each one consisting of 16 bits). The bits of each word are stored in a page of a corresponding number of memory cells of the matrix 105 (i.e., 16), which memory cells are associated with a single word line WL. The bit lines BL of each sector of the matrix 105 are grouped into 16 packets, each one associated with a different memory cell of every page. The memory device 100 receives an address of a selected word from the outside, and latches it into an address buffer 115. The address includes two portions for selecting the corresponding row and packet of columns in the matrix 105.

A converter 120 extracts the address from the address buffer 115, and then maps it to the address of the corresponding page of memory cells in the matrix 105. For this purpose, the converter 120 accesses a fuse bank 125 that includes a Read Only Memory (ROM) of the associative type, which stores the address of each defective row or column (in the memory matrix 105m) together with the address of the redundancy row or column, respectively (in the redundancy matrix 105r) to be used in substitution of it. The fuse bank 125 is generally programmed during an Electrical-Wafer Sorting (EWS) of the memory device 100 before its shipping. In this phase, the memory device 100 is tested to identify any defective rows and columns of the memory matrix 105m. Typically, such defects happen when pairs of rows and columns are not perfectly insulated from each other, so as to generate a corresponding short circuit (for example, because of a damage in their insulation trenches). Particularly, if the selected row and packet of columns are non-defective (i.e., their addresses are not included in the fuse bank 125), the converter 120 outputs the same address (for a page of memory cells in the memory matrix 105m) that is received from the address buffer 115. Conversely, when the selected row and/or packet of columns are defective (i.e., the corresponding row address and/or column address are included in the fuse bank 125), the converter 120 replaces the row/column address of the defective row/column with the row/column address of the corresponding redundancy row/column (in the redundancy matrix 105r), as indicated in the fuse bank 125.

In any case, the converter 120 supplies the row address and the column address (possibly converted) to the word line driver 110w and to the bit line driver 110b, respectively. The word line driver 110w and the bit line driver 110b select the corresponding word line WL and the corresponding packet of bit lines BL, respectively (either in the memory matrix 105m or in the redundancy matrix 105r), and bias them according to the required operation (read or write). The bit line driver 110b is also coupled with a data buffer 130. The data buffer 130 is used to latch the word being read from the selected page of memory cells during a reading operation, or to receive the value to be written into the selected page of memory cells during a writing operation.

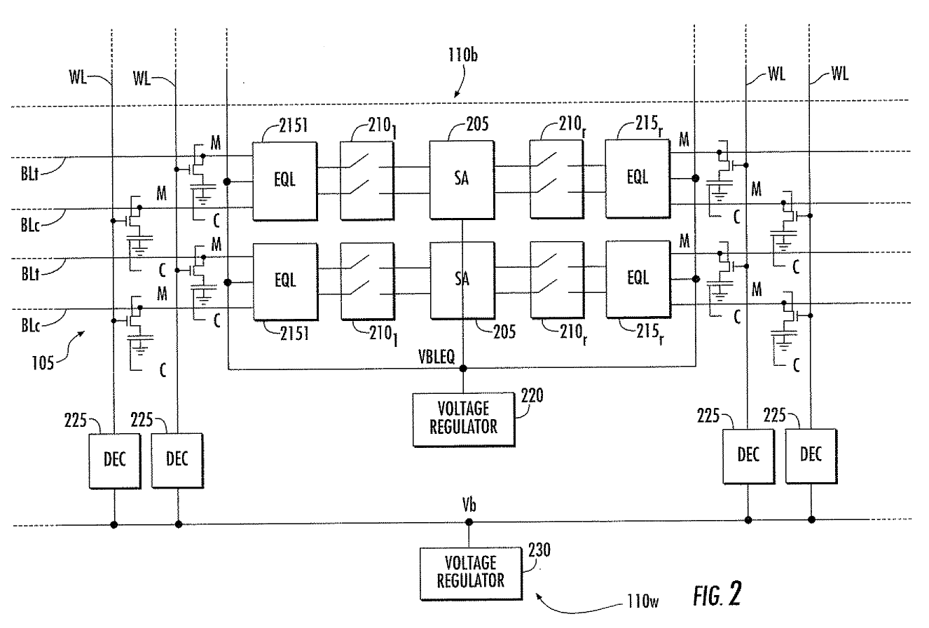

A functional diagram of the above-described memory device is shown in FIG. 2 (in the following, the elements corresponding to the ones of the preceding figures are denoted with the same references, and their explanation is omitted for ease of explanation). Particularly, the bit lines are organized in pairs (differentiated with the addition of the suffix “t” and “c”, i.e., BLt and BLc); the memory cells of each pair of corresponding columns are staggered to each other, so that the word lines WL (crossing them) are connected alternatively to the memory cells of the bit line BLt and of the bit line BLc. In this way, the memory cells of each row (connected to the corresponding word line WL) are all connected to the bit line BLt or to the bit line BLc of each pair (alternatively between each adjacent word line WL).

More specifically, each memory cell includes a storage capacitor C and a selection pass-transistor M. The capacitor C is connected between a reference terminal (providing a reference voltage, or ground) and a conduction terminal of the transistor M. The transistor M has another conduction terminal connected to the corresponding bit line BLt or BLc, and a gate terminal connected to the corresponding word line WL. The capacitor C is used to store a bit according to its charge; for example, the logic value 0 and the logic value 1 are associated with a null value and a power supply value Vcc (for example, 1.8-2V with reference to ground) of the voltage at the capacitor C. The transistor M is instead used to access the capacitor C during any reading or writing operation.

The bit line driver 110b includes a sense amplifier (SA) 205 for each pair of bit lines BLt, BLc in each sector of the matrix of memory cells M, C. The sense amplifier 205 is shared between a left side and a right side of the bit lines BLc, BLt. The sense amplifier 205 is connected to the left side of the bit lines BLt, BLc and to the right side of the bit lines BLt, BLc by a selection block 210l and a selection block 210r, respectively. The bit line driver 110b then includes an equalization block (EQL) 215l for the left side of the bit lines BLt, BLc and another equalization block 215r for the right side of the bit lines BLt, BLc. The equalization blocks 215l, 215r and the sense amplifiers 205 of the sector receive an equalization voltage VBLEQ from a common voltage regulator 220.

Moving now to the word line driver 110w, it includes a word line decoder (DEC) 225 for each word line WL. All the word line decoders 225 receive a set of biasing voltages (denoted as a whole with the reference Vb) from a set of common charge pumps (denoted as a whole with the reference 230); the charge pumps 230 generate the different voltages Vb from the voltage Vcc being received from the outside.

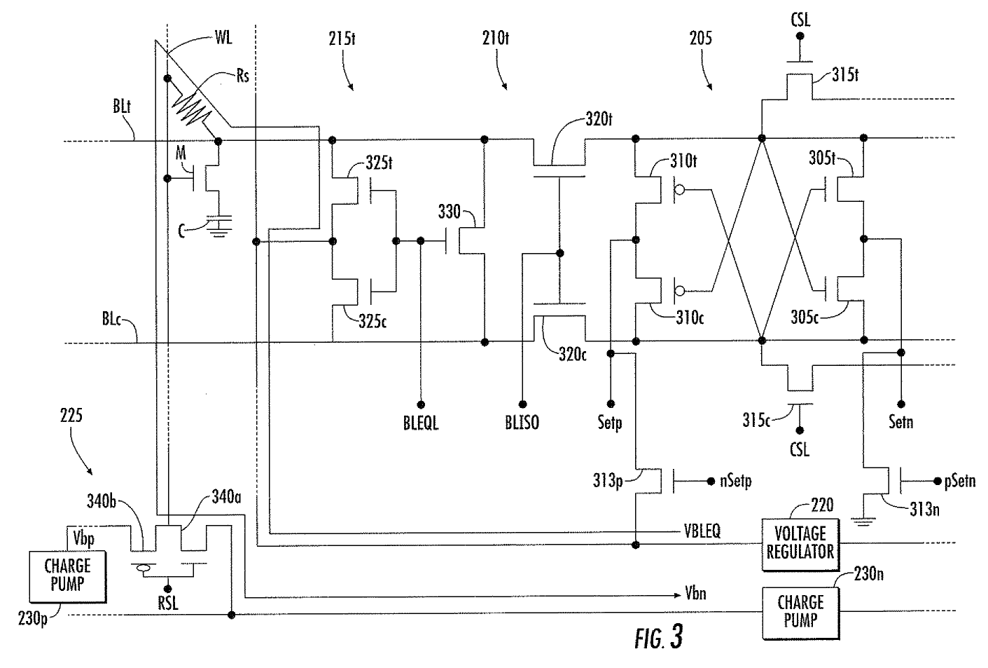

A simplified circuit scheme of a portion of the above-described memory device (relating to the left side of a pair of bit lines BLt, BLc and to a word line WL, with the corresponding components) is shown in FIG. 3. Particularly, the sense amplifier 205 has a cross-coupled structure defining a flip-flop. More specifically, an NMOS transistor 305t has a conduction terminal connected to the bit line BLt and another conduction terminal connected to a conduction terminal of an NMOS transistor 305c, which has another conduction terminal connected to the bit line BLc. Moreover, a PMOS transistor 310t has a conduction terminal connected to the bit line BLt and another conduction terminal connected to a conduction terminal of a PMOS transistor 310c, which has another conduction terminal connected to the bit line BLc. A gate terminal of the transistor 305t and a gate terminal of the transistor 310t are connected together to the bit line BLc; on the contrary, a gate terminal of the transistor 305c and a gate terminal of the transistor 310c are connected together to the bit line BLt.

A set signal Setn for the (NMOS) transistors 305t, 305c is supplied to the node in common between the transistor 305t and the transistor 305c; likewise, a set signal Setp for the (PMOS) transistors 310t, 310c is supplied to the node in common between the transistor 310t and the transistor 310c (from a controller of the memory device, not shown in the figure). An equalization pass-transistor 313n has a conduction terminal connected to the node in common between the transistor 305t and the transistor 305c, and another conduction terminal connected the ground terminal. A gate terminal of the transistor 313n receives an equalization signal pSetn (from the controller of the memory device).

In a similar manner, an equalization pass-transistor 313p has a conduction terminal connected to the node in common between the transistor 310t and the transistor 310c, and another conduction terminal connected to the (common) voltage regulator 220 for receiving the equalization voltage VBLEQ. A gate terminal of the transistor 313p receives an equalization signal nSetp (from the controller of the memory device). A selection pass-transistor 315t and a selection pass-transistor 315c are used to access the sense amplifier 205 at the bit line BLt and at the bit line BLc, respectively. For this purpose, the transistor 315t has a conduction terminal connected to the bit line BLt (between the transistors 305t and 310t), and another conduction terminal connected to the data buffer (not shown in the figure). Likewise, the transistor 315c has a conduction terminal connected to the bit line BLc (between the transistors 305c and 310c), and another conduction terminal connected to the data buffer. Both a gate terminal of the transistor 315t and a gate terminal of the transistor 315c receive a common selection signal CSL for the bit lines BLc, BLt (from the controller of the memory device).

The selection block 210l (connecting the sense amplifier 205 to the left side of the bit lines BLt, BLc) includes two pass-transistors 320t and 320c. The transistor 320t has a conduction terminal connected to the node in common between the transistors 305t and 310t, and another conduction terminal connected to the left side of the bit line BLt. Likewise, the transistor 320c has a conduction terminal connected to the node in common between the transistors 305c ands 310c, and another conduction terminal connected to the left side of the bit line BLc. A gate terminal of the transistor 320t and a gate terminal of the transistor 320c are connected together for receiving a selection signal BLISO of the left side of the bit lines BLc, BLt (from the controller of the memory device).

The equalization block 215l includes a pre-charging pass-transistor 325t having a conduction terminal connected to the bit line BLt and another conduction terminal connected to a conduction terminal of a pre-charging pass-transistor 325c, which has another conduction terminal connected to the bit line BLc. Moreover, an equalization pass-transistor 330 has a conduction terminal connected to the bit line BLt and another conduction terminal connected to the bit line BLc. The node in common between the transistor 325t and the transistor 325c receives the equalization voltage VBLEQ from the (common) voltage regulator 220. The transistors 325t, 325c and 330 have their gate terminals connected together for receiving an enabling signal BLEQL (from the controller of the memory device).

The word line selector 225 includes an NMOS transistor 340a, which has a conduction terminal connected to a (common) negative charge pump (differentiated with the reference 230n) providing a negative biasing voltage (differentiated with the reference Vbn)—for example, Vbn=−0.3V. The transistor 340a has another conduction terminal connected to a conduction terminal of a PMOS transistor 340b, which has another conduction terminal connected to a (common) positive charge pump (differentiated with the reference 230p) providing a positive biasing voltage (differentiated with the reference Vbp)—for example, Vbp=+2.9V. The transistors 340a and 340b have their gate terminals connected together for receiving a selection signal RSL of the word line WL (from the controller of the memory device).

In a stand-by condition, the signals pSetn and nSetp are at the null value, so as to open the transistors 313n and 313p, respectively; at the same time, the signal CSL is at the null value, so as to open the transistors 315t and 315c as well. The signals Setn and Setp are instead at the voltage VBLEQ (supplied by the voltage regulator 220). The signals BLEQL and BLISO are at the value Vcc. In this way, the transistors 325t and 325c are closed, so as to pre-charge the parasitic capacitors (not shown in the figure) associated with the bit line BLt (which the memory cell M, C is connected to) and the bit line BLc (associated thereto) to the voltage VBLEQ. Generally, the voltage VBLEQ has a value intermediate between the null value and the value Vcc (for example, VBLEQ=Vcc/2). Moreover, the transistor 330 is closed as well, so as to equalize the bit lines BLt and BLc (at the voltage VBLEQ). At the same time, the signal RSL is at the null value, so that the transistor 340a is closed and keeps the word line WL at the voltage Vbn (while the transistor 340b is open).

When a generic memory cell M, C (for example, between the bit line BLt and the word line WL) is selected for reading, the signal BLEQL is brought to the null value, so that all the transistors 325t, 325c and 330 are switched off; nevertheless, the bit lines BLt, BLc maintain the voltage VBLEQ for a short time (due to their parasitic capacitance). The signal RSL is then brought to the value Vcc. Therefore, the transistor 340a is switched off and the transistor 340b is switched on, thereby bringing the word line WL to the voltage Vbp. As a result, the transistor M is switched on, so that the voltage at the bit line BLt is updated according to the voltage at the capacitor C by charge sharing. Particularly, if the voltage at the capacitor C is at the null value (logic value 0) the bit line BLt is discharged lowering its voltage, whereas if the voltage at the capacitor C is at the value Vcc (logic value 1) the bit line BLt is charged increasing its voltage.

The signals nSetp and pSetn are then brought to the value Vcc, so as to switch on the transistors 313n and 313p, respectively; in this way, the sense amplifier 205 is switched on (being connected to the bit lines BLt and BLc through the transistor 320t and the transistor 320c, respectively). The sense amplifier 205 implements a positive feed-back, which amplifies any difference between the voltages at the bit lines BLt and BLc until reaching a stable condition wherein the bit lines BLt and BLc are at opposite values (0V and Vcc, or vice-versa). Particularly, if the voltage at the bit line BLt is lower then the voltage at the bit line BLc (i.e., the memory cell M,C stores the logic value 0), the (NMOS) transistor 305c becomes less conductive and the (PMOS) transistor 310c becomes more conductive, thereby increasing the voltage at the bit line BLc (towards the value Vcc). In turn, this makes the (PMOS) transistor 310t less conductive and the (NMOS) transistor 305t more conductive, thereby reducing the voltage at the bit line BLt (towards the null value). The same process continues until the voltage at the bit line BLt reaches the null value, and the voltage at the bit line BLc reaches the value Vcc. In a dual manner, if the voltage at the bit line BLt is higher then the voltage at the bit line BLc (i.e., the memory cell M, C stores the logic value 1), the voltage at the bit line BLc increases until reaching the value Vcc and the voltage at the bit line BLt reduces until reaching the null value.

The signal CSL can now be brought to the value Vcc, so as to switch on the transistors 315t and 315c that connect the sense amplifier 205 to the data buffer. As a result, the logic value 0 is read when the voltage at the bit line BLt is at the null value, or the logic value 1 is read when the voltage at the bit line BLt is at the value Vcc.

During the above-described reading operation, the capacitor C looses its charge (by charge sharing with the bit line BLt); indeed, the capacitance of the capacitor C is typically lower than the capacitance of the bit line BLt, since the last one cannot be reduced below a minimum value because of its length (for example, 20 fF for the capacitor C and 80 fF for the bit line BLt). However, the voltage at the capacitor C is automatically restored by the sense amplifier 205 (once it is switched on). Moreover, the capacitor C continuously looses its charge because of an unavoidable leakage. As a result, the memory device has to be periodically refreshed (for example, every some tens of ms) by reading the stored values and re-writing them.

When the memory cell M, C is instead selected for writing, the sense amplifier 205 is forced to the desired value; particularly, if the logic value 0 is to be written, the bit line BLt is brought to the null value (with the bit line BLc at the value Vcc). Conversely, if the logic value 1 is to be written, the bit line BLt is brought to the value Vcc (with the bit line BLc at the null value). At this point, the signal RSL is brought to the value Vcc. Therefore, the transistor 340a is switched off and the transistor 340b is switched on, thereby bringing the word line WL to the voltage Vbp. As a result, the transistor M is switched on, and then connects the capacitor C to the bit line BLt. In this way, the capacitor C is brought to the voltage at the bit line BLt (i.e., the null value for the logic value 0 or the value Vcc for the logic value 1).

In an actual memory device, the word lines and the bit lines may be not perfectly insulated from each other. For example, a resistive connection may be established between the word line WL and the bit line BLt. This is represented in the figure with a corresponding resistor Rs (connected between the word line WL and the bit line BLt). The resistor Rs has a resistance as low as the damage in the insulation between the word line WL and the bit line BLt (down to zero in the case of a short-circuit).

When this happens, the (defective) word line WL, the (defective) pair of bit lines BLt, BLc (including the bit line BLt), or both of them (according to the severity of the damage) are replaced by a corresponding redundancy word line and/or pair of redundancy bit lines (not shown in the figure). Nevertheless, a conduction path is established in the stand-by condition between the voltage regulator 220 (providing the voltage VBLEQ=Vcc/2) and the charge pump 230n (providing the voltage Vbn=−0.3V) through the transistor 325t, the bit line BLt, the resistor Rs, the word line WL, and the transistor 340a. Therefore, a leakage current flows along this conduction path as indicated by an elongated arrow in the figure (with a value equal to the voltage VBLEQ-Vbn divided by a whole resistance of the conduction path). It should be noted that even if this leakage current is relatively low, it causes a significant power loss.

Indeed, the leakage current has to be supplied by the charge pump 230n (providing a bootstrapped voltage, which is obtained multiplying the voltage Vcc by a suitable factor—such as 2-4); moreover, the charge pump 230n has a yield that may be very low in the stand-by condition (for example, down to 20-30%). Therefore, the current that the charge pump 230n absorbs from a power supply of the memory device because of the leakage current is equal to the leakage current multiplied by its multiplication factor and divided by its yield. Therefore, even a leakage current of a few μA involves the absorption of a current of tens of μA from the power supply (for example, from 1 μA to 1·3/0,2=15 μA).

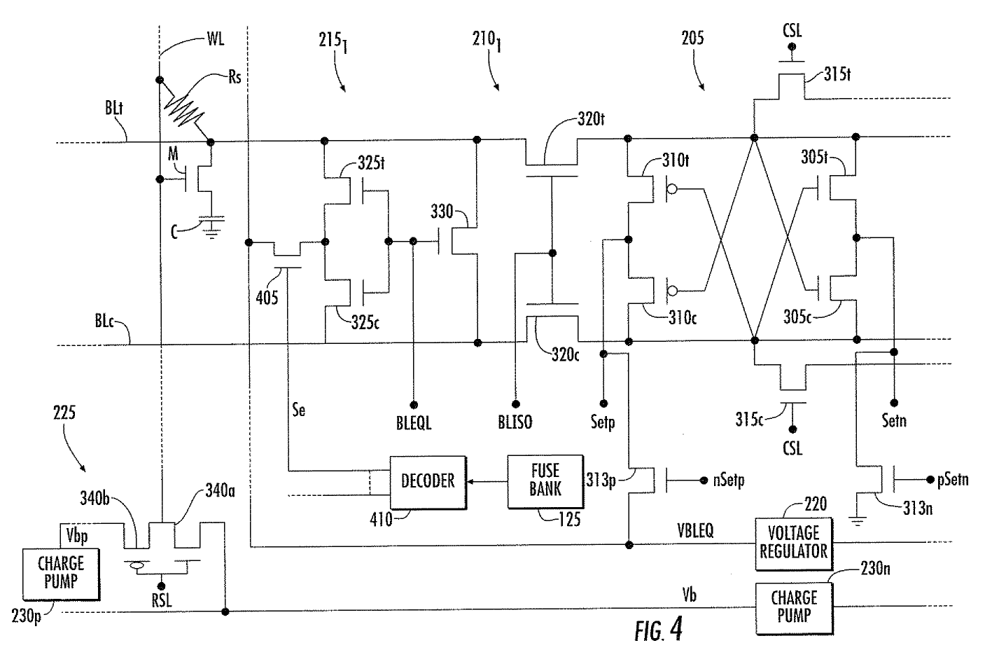

To address this problem, in the approach according to an embodiment of the present invention, a selector is inserted into the above-mentioned conduction path. For example, as shown in the FIG. 4, a pass-transistor 405 has a conduction terminal connected to the node in common between the transistors 325t and 325c, and another conduction terminal connected to a common line providing the voltage VBLEQ (from the voltage regulator 220). The transistor 405 receives an enabling signal Se at its gate terminal from a decoder 410. The decoder 410 generates the signal Se for each pair of bit lines individually according to the content of the fuse bank 125. Particularly, it the word line WL, the bit line BLt and the bit line BLc are all non-defective (i.e., their row/column addresses are not included in the fuse bank 125), the signal Se is brought to the value Vcc; in this way, the transistor 405 is switched on without interfering with operation of the equalization block 215l. Conversely, if one or more of the word line WL, the bit line BLt and the bit line BLc are defective (i.e., their row/column addresses are included in the fuse bank 125), the signal Se is brought to the null value; in this way, the transistor 405 is switched off and insulates the voltage regulator 220 from the equalization block 215l.

The proposed approach allows adding a resistor with a very high resistance (theoretically at an infinite value) to each conduction path associated with any defective word line and/or bit line; in this way, it is possible to remove (or at least substantially reduce) the corresponding leakage current, with a corresponding reduction in the power loss of the memory device. At the same time, a very low resistance (theoretically at a null value) is instead added to the non-defective word lines and bit lines, so as to avoid adversely affecting their operation. Therefore, the proposed approach allows obtaining the desired result (of reducing the power loss of the memory device being caused by the leakage current) without any substantial reduction of its working frequency.

For example, simulations of a standard memory device known in the art and of a memory device implementing the above-described approach have shown a reduction of the leakage current from 23 μA to 0.4 μA.

In the specific embodiment of the invention described above, the transistor 405 is arranged between the equalization block 215l and the voltage regulator 220. This arrangement has been found to be particularly advantageous for optimizing a layout of the memory device.

Moreover, in this case the transistor 405 is controlled according to the fuse bank 125. Therefore, it is possible to exploit information already available (for managing the replacement of the defective rows and columns by the corresponding redundancy rows and columns) for driving the transistor 405.

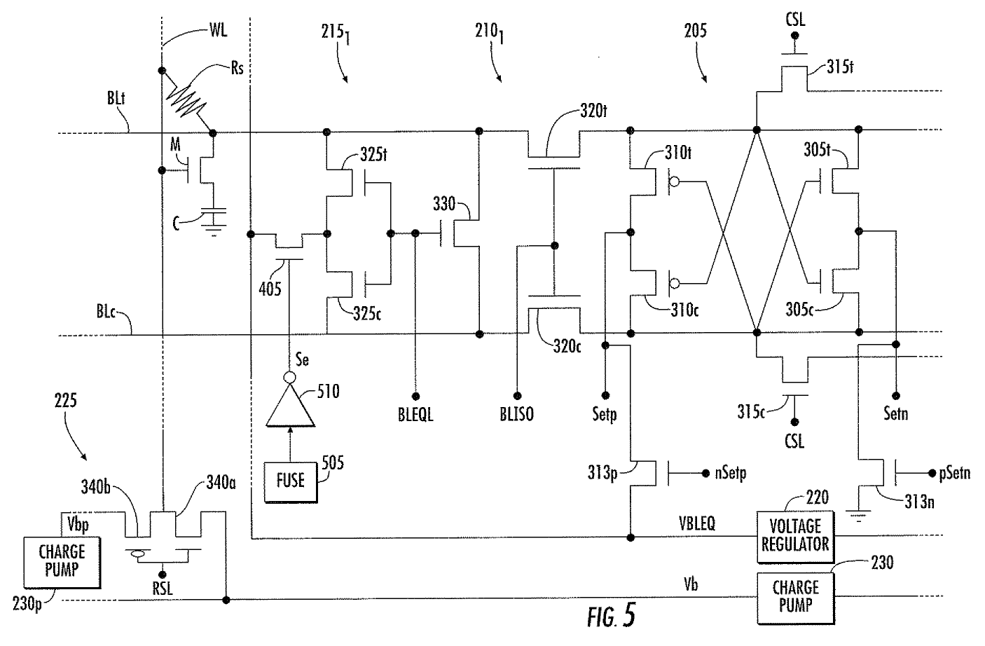

In a different embodiment of the invention, as shown in FIG. 5, the transistor 405 is instead controlled by a dedicated fuse 505 with a corresponding driver 510. Particularly, the fuse 505 is broken to assert a corresponding flag when the word line WL, the bit line BLt and/or the bit line BLc are defective (while the flag is de-asserted otherwise). The driver 510 provides the signal Se to the gate terminal of the transistor 405 according to the state of the fuse 505. Particularly, if the fuse 505 is not broken (corresponding flag de-asserted) the signal Se is brought to the value Vcc (so as to switch on the transistor 405); conversely, if the fuse 505 is broken (corresponding flag asserted) the signal Se is brought to the null value (so as to switch off the transistor 405).

This implementation strongly simplifies the routing of the signals in the memory device, since no dedicated connection is required from the (common) fuse bank and decoder to every transistor 405. However, in this case a fuse 505 has to be added to store locally the information required to drive each transistor 405.

Naturally, to satisfy local and specific requirements, a person skilled in the art may apply to the approach described above many logical and/or physical modifications and alterations. More specifically, although this approach has been described with a certain degree of particularity with reference to preferred embodiment(s) thereof, it should be understood that various omissions, substitutions and changes in the form and details as well as other embodiments are possible. Particularly, the same approach may even be practiced without the specific details (such as the numerical examples) set forth in the preceding description to provide a more thorough understanding thereof; conversely, well-known features may have been omitted or simplified to not obscure the description with unnecessary particulars. Moreover, it is expressly intended that specific elements and/or method steps described in connection with any embodiment of the disclosed approach may be incorporated in any other embodiment as a matter of general design choice.

Particularly, similar considerations apply if the memory device has a different structure or includes equivalent components; moreover, the components may be separate to each other or combined together, in whole or in part. For example, the memory cells may be arranged in whatever number of sectors (down to a single one), each one including whatever number of rows and/or columns, and the memory device may be provided with whatever number of redundancy rows and/or columns. Likewise, it is possible to implement the bit line driver and/or the word line driver with equivalent circuits.

Nothing prevents replacing each pass-transistor (between the voltage regulator and the corresponding equalization block) with any other suitable selector, which may be driven to different low resistance or high resistance (when the corresponding word line and pair of bit lines are non-defective or defective, respectively). Alternatively, each pass transistor may be associated with a group of (one or more) word lines, and/or with a group of (one or more) pairs of bit lines.

Similar considerations apply if the voltage regulator (providing the equalization voltage) is replaced with an equivalent component. In any case, the proposed approach lends itself to be applied to different memory devices with different architectures (for example, wherein the bit lines are not organized in pairs).

Likewise, the above-mentioned biasing voltages provided by the charge pumps are merely illustrative. Moreover, a biasing voltage at the null value (instead of at a negative value) may also be provided directly by the ground terminal, without any charge pump.

The possibility of arranging each pass transistor in a different position along its conduction path is not excluded (for example, within the equalization block, along the pair of bit lines, along the word line, in the word line selector, or between the word line selector and the charge pump).

Similar considerations apply if the decoder is replaced with an equivalent component for driving the pass-transistors according to the content of the fuse bank; moreover, the fuses may be replaced with floating gate transistors (for example, of a ROM or an EEPROM), or any other storage element.

Although in the preceding description reference has been made to an embodiment based on a central fuse bank and another embodiment based on local individual fuses, this is not to be interpreted in a limitative manner. For example, it is possible to implement a combined approach, or any other technique for controlling the pass transistors individually.

Even though the proposed approach has been described with a great emphasis in respect of a specific DRAM, nothing prevents applying it to a DRAM with a different structure; for example, similar considerations apply to a Fast Page Mode (FPM) DRAM, an Extended Data Out (EDO) DRAM, a Pseudostatic (PS) DRAM, and the like. In any case, the proposed approach lends itself to be applied to an E²PROM, or more generally to any other (volatile or nonvolatile) memory device.

It should be readily apparent that the proposed structure might be part of the design of an integrated circuit. The design may also be created in a programming language; moreover, if the designer does not fabricate chips or masks, the design may be transmitted by physical means to others. In any case, the resulting integrated circuit may be distributed by its manufacturer in raw wafer form, as a bare die, or in packages. Moreover, the proposed approach may be integrated with other circuits in the same chip, or it may be mounted in intermediate products (such as mother boards) and coupled with one or more other chips (such as a microprocessor).

In addition, any number of the proposed memory devices may be used in complex systems; examples of these systems are computers, mobile telephones, MP3 players, digital still cameras, and the like.

At the end, the proposed approach may be practiced with equivalent methods (by using similar steps, removing some steps being non-essential, or adding further optional steps); moreover, the steps may be performed in a different order, concurrently or in an interleaved way (at least in part).

That which is claimed:

1. A memory device comprising:
a matrix of memory cells arranged in a plurality of rows and columns including redundancy rows and columns for replacing defective rows and columns;
a plurality of bit lines each being connected to the memory cells of a corresponding column;
a plurality of word lines each being connected to the memory cells of a corresponding row;
a bit line driver for biasing the bit lines;
a word line driver for biasing the word lines;
a plurality of selectors each being arranged along a potential conduction path between the bit line driver and the word line driver through a set of corresponding word lines and bit lines; and
a selection driver for setting each selector to a first resistance if the corresponding rows and columns are non-defective and to a second resistance different than the first resistance if at least one of the corresponding rows and columns is defective.

2. The memory device according to claim 1, wherein each selector includes a pass-transistor, the selection driver closing each pass-transistor if the corresponding rows and columns are non-defective and opening each pass-transistor if at least one of the corresponding rows and columns is defective.

3. The memory device according to claim 2, wherein each selector is arranged along a potential conduction path between the bit line driver and the word line driver through a corresponding single word line and a corresponding single pair of bit lines.

4. The memory device according to claim 3, wherein the bit line driver includes a plurality of equalization blocks each for equalizing a corresponding pair of bit lines to an equalization voltage during a reading operation, and a voltage regulator for providing the equalization voltage to the equalization blocks, and each selector being arranged in the corresponding conduction path between the voltage regulator and the word line driver.

5. The memory device according to claim 4, wherein the word line driver includes a corresponding word line decoder for selecting one of the plurality of word lines, and a charge pump for providing selected biasing voltages to the word lines through the corresponding word line decoders, and each selector being arranged in the corresponding conduction path between the voltage regulator and the charge pump.

6. The memory device according to claim 5, wherein each selector is connected between the voltage regulator and the corresponding equalization block.

7. The memory device according to claim 6, further comprising a storage structure for storing an indication of the defective rows and columns, the selection driver being adapted to set the resistance of the selectors based upon the stored indications in the storage structure.

8. The memory device according to claim 7, further including a converter for causing a corresponding redundancy row and a corresponding redundancy column to be accessed instead of each defective row and each defective column, respectively, according to the stored indications in the storage structure.

9. The memory device according to claim 7, wherein the storage structure includes a storage element for each selector, and the selection driver includes a driving element for each selector, each driving element being adapted to set the resistance of the corresponding selector according to a content of the corresponding storage element.

10. The memory device according to claim 1, wherein the memory device is a DRAM.

11. An electronic system comprising:
at least one memory device including
a matrix of memory cells arranged in a plurality of rows and columns including redundancy rows and columns for replacing defective rows and columns,
a plurality of bit lines each being connected to the memory cells of a corresponding column,
a plurality of word lines each being connected to the memory cells of a corresponding row,
a bit line driver for biasing the bit lines,
a word line driver for biasing the word lines,
a plurality of selectors each being arranged along a potential conduction path between the bit line driver and the word line driver through a set of corresponding word lines and bit lines, and
a selection driver for setting each selector to a first resistance if the corresponding rows and columns are non-defective and to a second resistance different than the first resistance if at least one of the corresponding rows and columns is defective.

12. The electronic system according to claim 11, wherein each selector includes a pass-transistor, the selection driver closing each pass-transistor if the corresponding rows and columns are non-defective and opening each pass-transistor if at least one of the corresponding rows and columns is defective.

13. The electronic system according to claim 12, wherein each selector is arranged along a potential conduction path between the bit line driver and the word line driver through a corresponding single word line and a corresponding single pair of bit lines.

14. The electronic system according to claim 13, wherein the bit line driver includes a plurality of equalization blocks each for equalizing a corresponding pair of bit lines to an equalization voltage during a reading operation, and a voltage regulator for providing the equalization voltage to the equalization blocks, and each selector being arranged in the corresponding conduction path between the voltage regulator and the word line driver.

15. The electronic system according to claim 14, wherein the word line driver includes a corresponding word line decoder for selecting one of the plurality of word lines, and a charge pump for providing selected biasing voltages to the word lines through the corresponding word line decoders, and each selector being arranged in the corresponding conduction path between the voltage regulator and the charge pump.

16. The electronic system according to claim 15, wherein each selector is connected between the voltage regulator and the corresponding equalization block.

17. The electronic system according to claim 16, wherein the memory device further comprises a storage structure for storing an indication of the defective rows and columns, the selection driver being adapted to set the resistance of the selectors based upon the stored indications in the storage structure.

18. The electronic system according to claim 17, wherein the memory device further comprises a converter for causing a corresponding redundancy row and a corresponding redundancy column to be accessed instead of each defective row and each defective column, respectively, according to the stored indications in the storage structure.

19. The electronic system according to claim 17, wherein the storage structure includes a storage element for each selector, and the selection driver includes a driving element for each selector, each driving element being adapted to set the resistance of the corresponding selector according to a content of the corresponding storage element.

20. A method for operating a memory device including a matrix of memory cells arranged in a plurality of rows and columns, a plurality of bit lines each being connected to the memory cells of a corresponding column, a plurality of word lines each being connected to the memory cells of a corresponding row, a bit line driver for biasing the bit lines, a word line driver for biasing the word lines, a plurality of selectors each being arranged along a potential conduction path between the bit line driver and the word line driver through a set of corresponding word lines and bit lines, the method comprising:
replacing defective rows and columns with redundancy rows and columns of memory cells in the matrix; and
setting each one of the plurality of selectors to a first resistance if the corresponding rows and columns are non-defective and to a second resistance different than the first resistance if at least one of the corresponding rows and columns is defective.

21. The method according to claim 20, wherein each selector includes a pass-transistor; and wherein setting includes closing each pass-transistor if the corresponding rows and columns are non-defective and opening each pass-transistor if at least one of the corresponding rows and columns is defective.

22. The method according to claim 21, wherein each selector is arranged along a potential conduction path between the bit line driver and the word line driver through a corresponding single word line and a corresponding single pair of bit lines.

23. The method according to claim 22, wherein the bit line driver includes a plurality of equalization blocks each for equalizing a corresponding pair of bit lines to an equalization voltage during a reading operation, and a voltage regulator for providing the equalization voltage to the equalization blocks, and each selector being arranged in the corresponding conduction path between the voltage regulator and the word line driver.

24. The method according to claim 23, wherein the word line driver includes a corresponding word line decoder for selecting one of the plurality of word lines, and a charge pump for providing selected biasing voltages to the word lines through the corresponding word line decoders, and each selector being arranged in the corresponding conduction path between the voltage regulator and the charge pump.

25. The method according to claim 24, wherein each selector is connected between the voltage regulator and the corresponding equalization block.

26. The method according to claim 25, wherein the memory device includes a storage structure for storing an indication of the defective rows and columns, the resistance of the selectors being set based upon the stored indications in the storage structure.

27. The method according to claim 26, wherein the memory device further includes a converter for causing a corresponding redundancy row and a corresponding redundancy column to be accessed instead of each defective row and each defective column, respectively, according to the stored indications in the storage structure.

28. The method according to claim 26, wherein the storage structure includes a storage element for each selector, and the selection driver includes a driving element for each selector, each driving element being adapted to set the resistance of the corresponding selector according to a content of the corresponding storage element.
